(19) United States
(12) Patent Application Publication
(10) Pub. No.: US 2024/0222249 A1
(43) Pub. Date: Jul. 4, 2024

(54) INTEGRATED CIRCUIT DEVICE PACKAGE SUBSTRATES WITH GLASS CORE LAYER HAVING ROUGHENED SURFACES

(71) Applicant: Intel Corporation, Santa Clara, CA (US)

(72) Inventors: Jeremy D. Ecton, Gilbert, AZ (US); Srinivas V. Pietambaram, Chandler, AZ (US); Gang Duan, Chandler, AZ (US); Brandon Christian Marin, Gilbert, AZ (US); Suddhasattwa Nad, Chandler, AZ (US); Oladeji T. Fadayomi, Maricopa, AZ (US); Manuel Gadogbe, Queen Creek, AZ (US); Matthew L. Tingey, Mesa, AZ (US)

(73) Assignee: Intel Corporation, Santa Clara, CA (US)

(21) Appl. No.: 18/148,355

(22) Filed: Dec. 29, 2022

(51) Int. Cl. H01L 23/498; H01L 21/48; H01L 23/15

(52) U.S. Cl. CPC H01L 23/49827; H01L 21/486; H01L 23/15; H01L 23/49822; H01L 24/16; H01L 2224/16227

(57) ABSTRACT

In one embodiment, an integrated circuit package substrate includes a glass layer having at least one roughened surface (e.g., with an average roughness above 100 nm) and a metal (e.g., a metal trace or metal via) in contact with the roughened surface of the glass layer.

### BACKGROUND

Integrated circuit devices may utilize package substrates that include glass or glass-based core layers. However, the glass layer may introduce adhesion issues between the smooth glass interface and copper features of the package substrate, e.g., traces, pads, or through-glass vias (TGVs). Furthermore, thin glass may present handling challenges when used in wet tool processes, as the relatively small frictional forces from the smooth glass surface can result in panel movement during agitation within the chamber.

### BRIEF DESCRIPTION OF THE DRAWINGS

FIGS. 1A-1D illustrate example glass structures with roughened surfaces in accordance with embodiments herein.

FIGS. 2A-2B illustrate example processes of forming through glass vias on a glass substrate in accordance with embodiments herein.

FIG. 3 illustrates an example glass panel that is divided into a plurality of portions with selectively roughened areas in accordance with embodiments herein.

FIG. 4 illustrates an example process of selectively roughening portions of a glass panel in accordance with embodiments herein.

FIG. 5 is a simplified cross-sectional view of an example portion of a substrate of an integrated circuit component, the substrate comprising a glass core.

FIG. 6 is a top view of a wafer and dies that may be included in a microelectronic assembly, in accordance with any of the embodiments disclosed herein.

FIG. 7 is a cross-sectional side view of an integrated circuit device that may be included in a microelectronic assembly, in accordance with any of the embodiments disclosed herein.

FIG. 8 is a cross-sectional side view of an integrated circuit device assembly that may include a microelectronic assembly, in accordance with any of the embodiments disclosed herein.

FIG. 9 is a block diagram of an example electrical device that may include a microelectronic assembly, in accordance with any of the embodiments disclosed herein.

### DETAILED DESCRIPTION

The demand for the miniaturization of computing device form factors and increased levels of integration to achieve high performance in computing devices is helping drive the development of sophisticated packaging approaches in the semiconductor industry. Die partitioning, in which a desired functionality is implemented by multiple interconnected smaller integrated circuit dies can help enable form factor miniaturization and high performance, without the yield issues associated with implementing the desired functionality with a single larger integrated circuit die. However, die-to-die interconnections having a fine pitch are needed to realize the full potential of die partitioning. One 2.5D packaging approach to enable high-density interconnects between heterogeneous dies on a single package employs small silicon bridge chips embedded in the package, which enables the placement of high density die-to-die connections only where needed. Standard flip-chip assembly is used for power delivery and to connect high-speed signals directly from integrated circuit dies to the package substrate. This can be a simpler and lower cost 2.5D packaging approach than an expensive silicon interposer with through silicon vias (TSVs).

For future generations of die partitioning, bridges that can connect dies at bump pitches of 25 microns or less are expected to be needed. Some existing approaches of using silicon bridge chips embedded in a 2.5D packaging approach can suffer from a high cumulative variation in the thickness of the bumps employed for attaching dies to a substrate, which can cause yield issues. As the number of embedded bridges in a package substrate increases as more complex die partitioning schemes are desired, the cost of embedding the bridges can increase and yields may suffer. Alternate architectures and/or approaches have been proposed, such as stacking integrated circuit dies vertically or using silicon bridges with embedded functional integrated circuit dies and/or through-silicon vias.

Another option for enabling fine die-to-die interconnections is incorporating a thin glass core into the substrate package. As compared to a conventional epoxy core, a glass core offers several advantages including a higher plated through hole density, lower signal loss, and lower total thickness variation (TTV). As used herein, a glass may refer to a dielectric material that includes Silicon and Oxygen, e.g., as silica (SiO₂), a doped silicate (e.g., doped with Boron (e.g., borosilicate glass), Phosphorous, or other dopants), another type of silicate, or a material with some other mixture of Silicon and Oxygen (SiOₓ).

However, a glass core layer may introduce adhesion issues between the smooth glass interface (e.g., with Ra<100 nm) and metal features of the package substrate, e.g., traces, pads, or through-glass vias (TGVs). Furthermore, thin glass may present handling challenges when used in wet tool processes, as the relatively small frictional forces from the smooth glass surface can result in panel movement during agitation within the chamber. Some solutions to the adhesion issue have focused on use of buffer layers between the glass and metal; however, inserting a buffer layer between the glass and metal requires additional, complicated processing steps along with a potentially higher cost when compared to patterning the metal directly onto the glass.

Embodiments herein may accordingly implement a roughened glass surface within an integrated circuit device, e.g., in a glass or glass-based core layer of the package substrate of the integrated circuit device. Surfaces may be characterized by an average surface roughness Ra (alternatively, Rq, the root mean square (RMS) surface roughness, Rv, the maximum profile valley depth, or Rmax, the maximum roughness depth, may be employed as a metric of surface roughness). Throughout the present disclosure, Ra may be the primary metric of surface roughness. As used herein, a “roughened surface” of a glass layer may refer to a surface with a substantially higher roughness than an adjacent or other surface of the glass layer (e.g., a roughness that is at least 10% higher). For instance, in certain embodiments, a “roughened surface” may refer to a surface of the glass layer with an average roughness of greater than or equal to 100 nm, whereas a “smooth surface” may refer to a surface of the glass layer with an average roughness of less than 100 nm. However, in other embodiments, a “roughened surface” may refer to a surface of the glass layer with an average roughness of greater than or equal to 20, 30, or 50 nm, whereas a “smooth surface” may refer to a surface of the glass layer with an average roughness of less than 20, 30, or 50 nm, respectively (e.g., 10 nm).

The glass layer may be implemented with a uniformly roughened surface, i.e., roughened across the entire surface of glass, or may be implemented with non-uniform or selective roughening in specific locations of the glass layer. As an example, in the case of selective roughening, only a top surface of the glass may be roughened, and an area around the TGV region may be left un-roughened. In some instances, however, it may be advantageous to selectively roughen certain keep out zones (KOZs) or non-active areas of the glass layer, e.g., to improve handling and/or eliminate film delamination on the surface of the glass during dicing into smaller form factor (e.g., quarter panel, unit, etc.). Roughening the surface of the glass layer, or portions thereof, may allow for improved adhesion between the glass and metal deposited thereon, which can provide improved processing yield in certain instances. In addition, roughening the glass layer can aid with friction for touch points between the glass and the processing tools, which can provide improved handling/line yields.

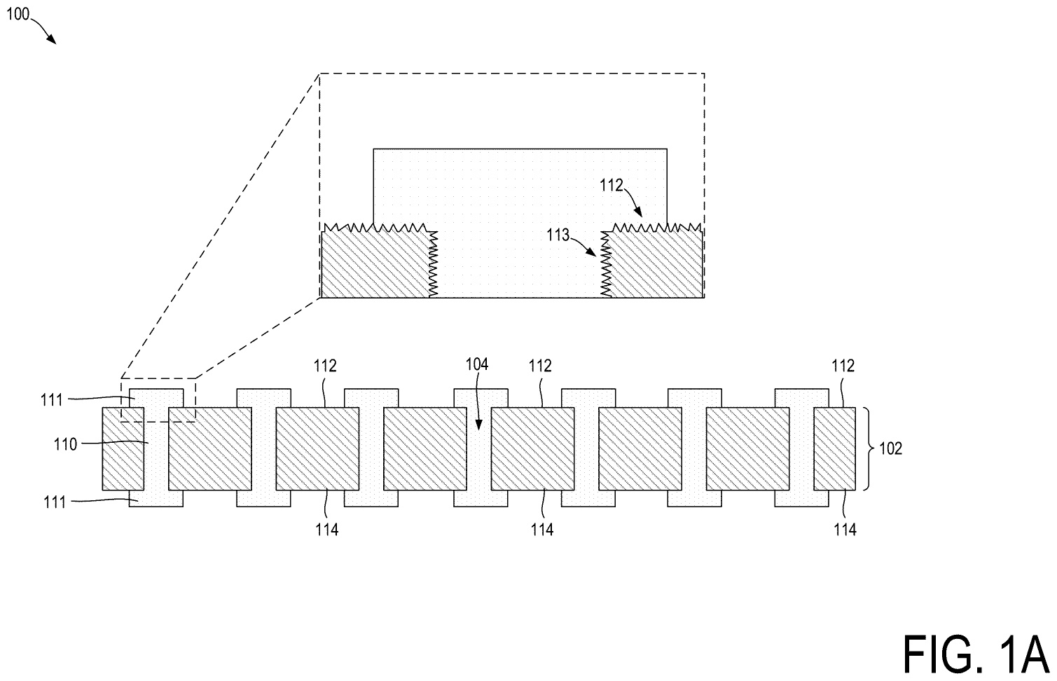

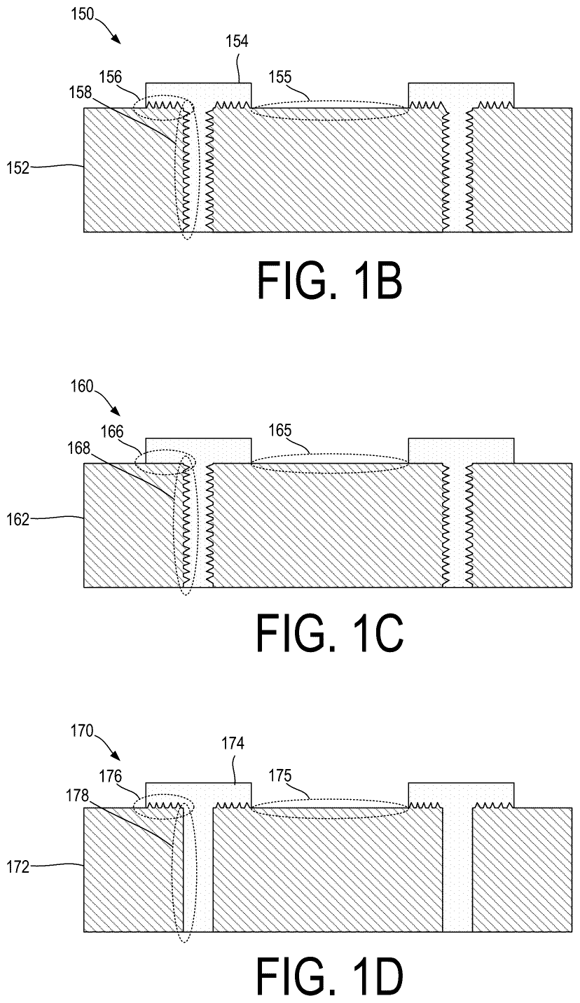

FIGS. 1A-1D illustrate example glass structures 100, 150, 160, 170 with roughened surfaces in accordance with embodiments herein. In certain embodiments, the structures 100, 150, 160 will become a glass core that can be utilized in an integrated circuit device package substrate. Referring first to FIG. 1A, the structure 100 includes a layer of glass 102 in which holes 104 have been created and filled with a metal (e.g., copper or titanium) to create through-glass vias (TGVs) 110. The vias 110 are formed with pad portions 111 on both an upper surface 112 and a bottom surface 114 of the layer of glass 102.

In accordance with embodiments herein, one of more surfaces of the layer of glass 102 may be roughened, e.g., to promote adhesion between the metal vias 110 and pad portions 111 and the layer of glass 102. For example, in some embodiments, the upper surface 112 and bottom surface 114 may each be roughened. Moreover, in certain embodiments, an inside surface 113 of the holes 104 in the layer of glass 102 may be roughened, e.g., in addition to or in lieu of roughening the upper surface 112 and bottom surface 114. The roughening of the surface(s) may be implemented by a wet process in certain embodiment, whereby a liquid glass etchant is used to roughen the surface. Example glass etchants include solutions that include sodium hydroxide (NaOH), hydrofluoric acid (HF), or other known glass etchants. In addition, in some embodiments, a dry etch (e.g., plasma) may also be used to roughen surface(s) of the layer of glass 102. In certain embodiments, the surface(s) of the layer of glass 102 may be patterned with a fine array of hard mask material and then the glass can be etched to create deep “anchors” into the layer of glass 102. The hard mask material may also be used to selectively roughen specific areas of a panel, e.g., keep out zones (KOZs) of the panel as described below, or other areas of the panel. Selective roughening may take place using a shutter system and/or a hard mask. In other embodiments, the surface(s) of the glass may be roughened using a course grinding process.

Referring now to FIGS. 1B-1D, the example structures 150, 160, 170 illustrate examples of selective roughening that may be implemented in certain embodiments—that is, where roughening has been applied to selective portions of the layer of glass. For instance, in the example structure 150 shown in FIG. 1B, the surfaces of the layer of glass 152 (e.g., 156, 158) that are in contact with the metal vias 154 are roughened (e.g., have an average roughness of greater than 100 nm), while other surfaces of the layer of glass 152 (e.g., 155) remain smooth (e.g., an average roughness of less than 100 nm). In contrast, in the example structure 160 shown in FIG. 1C, only surfaces within the holes (e.g., 168) of the of the layer of glass 162 are roughened (e.g., have an average roughness of greater than 100 nm), while other surfaces of the layer of glass 162 (e.g., 165, 166) remain smooth (e.g., an average roughness of less than 100 nm). In further contrast, in the example structure 170 shown in FIG. 1D, only portions of the top surface (e.g., 176) of the layer of glass 172 that are in contact with the metal vias 174 are roughened (e.g., have an average roughness of greater than 100 nm), while other surfaces of the layer of glass 172 (e.g., 175, 176) remain smooth (e.g., an average roughness of less than 100 nm). Other selective roughening patterns may be applied as well without departing from the scope of the present disclosure.

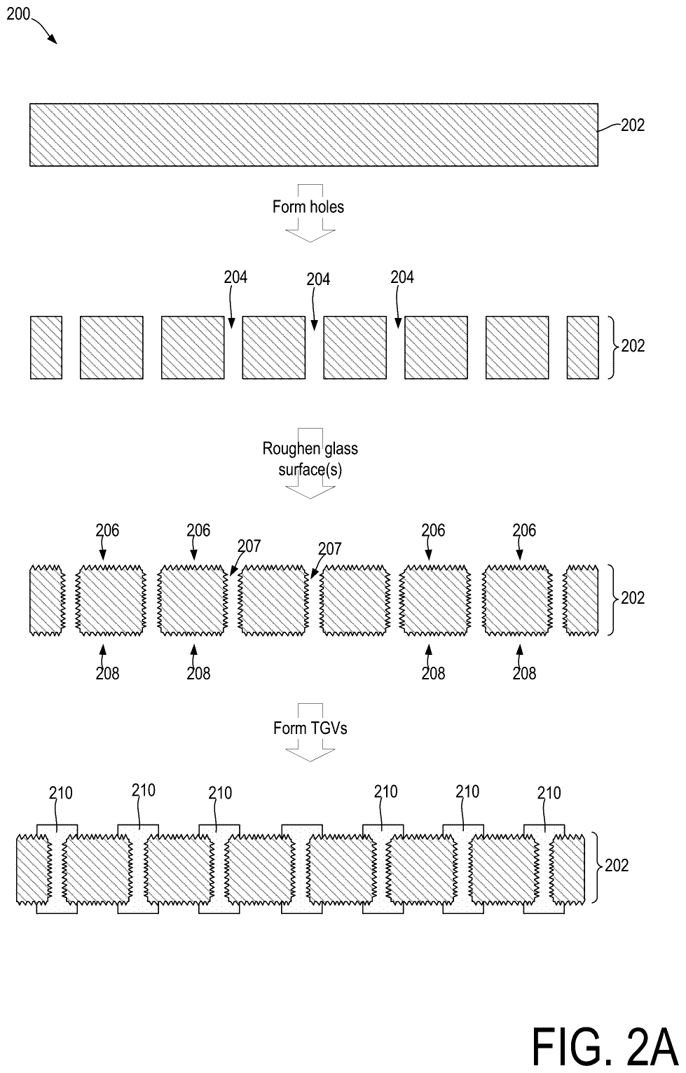

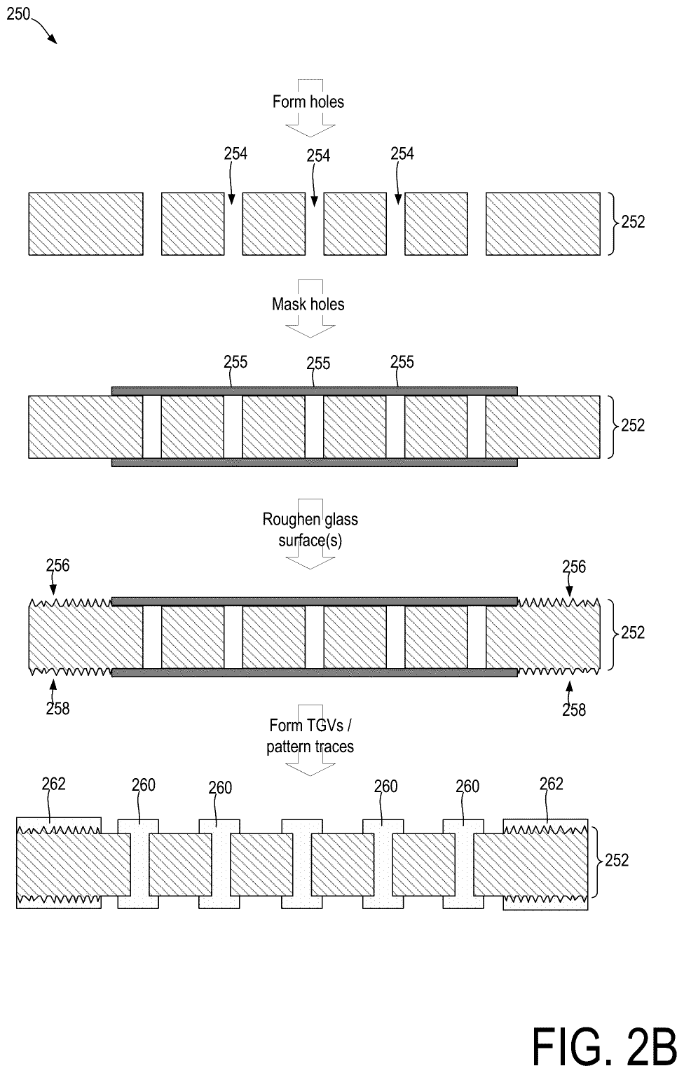

FIGS. 2A-2B illustrate example processes of forming through glass vias on a glass substrate in accordance with embodiments herein. In particular, FIG. 2A illustrates an example process 200 of roughening a glass substrate and forming TGVs in the substrate, and FIG. 2B illustrates an example process 250 of selectively roughening and patterning metal traces 212 on the roughened surfaces of the glass substrate, both in accordance with embodiments herein. The processes 200, 250 can be implemented or performed, for example, by an integrated circuit component manufacturer. The example process may include additional, fewer, or different operations than those shown or described below. In some embodiments, one or more of the operations shown include multiple operations, sub-operations, etc.

Referring to FIG. 2A, holes 204 are formed in a layer of glass 202, and then the exposed surfaces of the layer of glass 202 are roughened to promote adhesion of a metal to the surfaces. The roughened surfaces include a top surface 206 of the layer of glass 202, a bottom surface 208 of the layer of glass 202, and the surfaces 207 inside the holes 204 formed within the layer of glass 202. The roughening may be done using a wet etch process, e.g., where a liquid is deposited or otherwise placed in contact with the surfaces of the glass, or by a dry etch process, e.g., where plasma is flowed into a chamber in which the glass resides. The roughening may aid in the later formation of metal TGVs 210, e.g., by aiding with adhesion of the metal to the glass, and/or with deposition of metal traces on one or both of the sides 206, 208 of the layer of glass 202. Though the entirety of the inner surface of the holes 204 is shown as being roughened in FIG. 2A, in some embodiments, only a portion of the surfaces within the holes 204 may be roughened. For instance, where a dry etch process is used, the plasma may not enter the entirety of the holes 204 and may accordingly only roughen the upper-most and bottom-most surfaces within the holes 204 (i.e., the portions nearest the top surface 206 and bottom surface 208, respectively).

Referring now to FIG. 2B, holes 254 are formed in a layer of glass 252, similar to the process 200. The holes 254 are then masked with a hard mask material 255 and the exposed surfaces of the layer of glass 252 (i.e., the exposed top surface 256 and exposed bottom surface 258) are then roughened to promote adhesion of a metal to the surfaces. The hard mask material 255 is then removed and TGVs 260 are formed in the holes 254, and metal traces 262 are patterned on the roughened surfaces of the layer of glass 252.

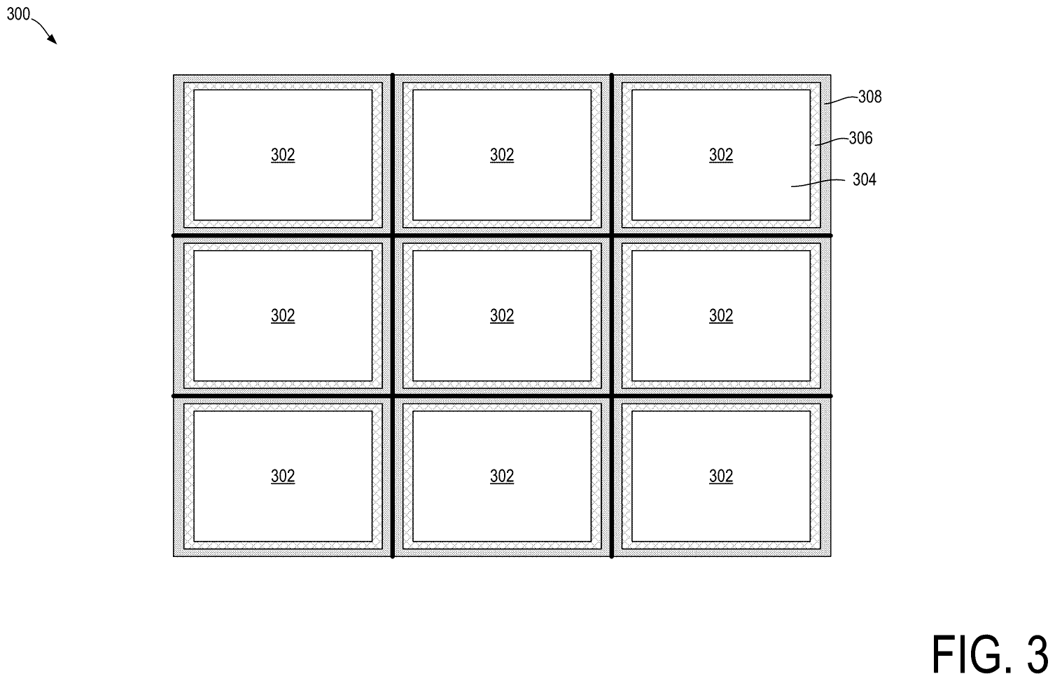

FIG. 3 illustrates an example glass panel 300 that is divided into a plurality of portions 302 with selectively roughened areas 306, 308 in accordance with embodiments herein. In certain embodiments, the panel portions 302 may be cut or “diced” from the panel 300 so that they may be used separately, e.g., each as a core layer in a package substrate for an integrated circuit device. In the example shown, each portion 302 includes an inner active area 304, which may represent an area in which TGVs, traces, circuitry, etc. may be formed or otherwise placed for a package substrate. The dark shaded area 308 of each panel portion 302 in may represent a keep out zone (KOZ) that may be used (e.g., by a machine) for handling the panel portion 302 during/after dicing and/or during one or more manufacturing steps. Thus, the KOZ may represent an area in which no traces, circuitry, TGVs, etc. may be placed.

In certain embodiments, the area 308 of each panel portion 302 may be roughened, e.g., using a wet or dry etch process as described herein, which may increase friction for handling purposes and potentially lead to better handling/line yields in the manufacturing process. The areas 308 may be selectively roughened as shown, i.e., leaving the inner active areas 304 without roughening. However, further roughening may be performed within the active areas 304 in other embodiments, e.g., selective roughening on certain surfaces (or portions of surfaces) within the areas 304 or within holes formed within the areas 304 (e.g., for TGVs). Further, in some embodiments, a small border area 306 (hatched in FIG. 3) within the active area 304 of each panel portion 302 may be roughened in addition to the KOZ areas 308, e.g., to allow a buffer for alignment errors by tools used in the manufacturing process (e.g., a frame clamp used to hold the panel portion 302 during processing).

Roughening of surfaces within the areas 306, 308 may provide certain advantages. For instance, the roughening may provide for more friction and prevent slippage by one or more tools used to hold the panel portions 302 in manufacturing processes. Further, in some cases, delamination of metal from the glass surface may begin at the edges of the panel portions (e.g., after dicing or during handling) and propagate toward the center of the active region 304. Roughening the edges as shown may provide the glass-to-metal adhesion benefits described herein, while also avoiding potential negative electrical effects that might be caused by roughened surfaces in other areas of the active region 304.

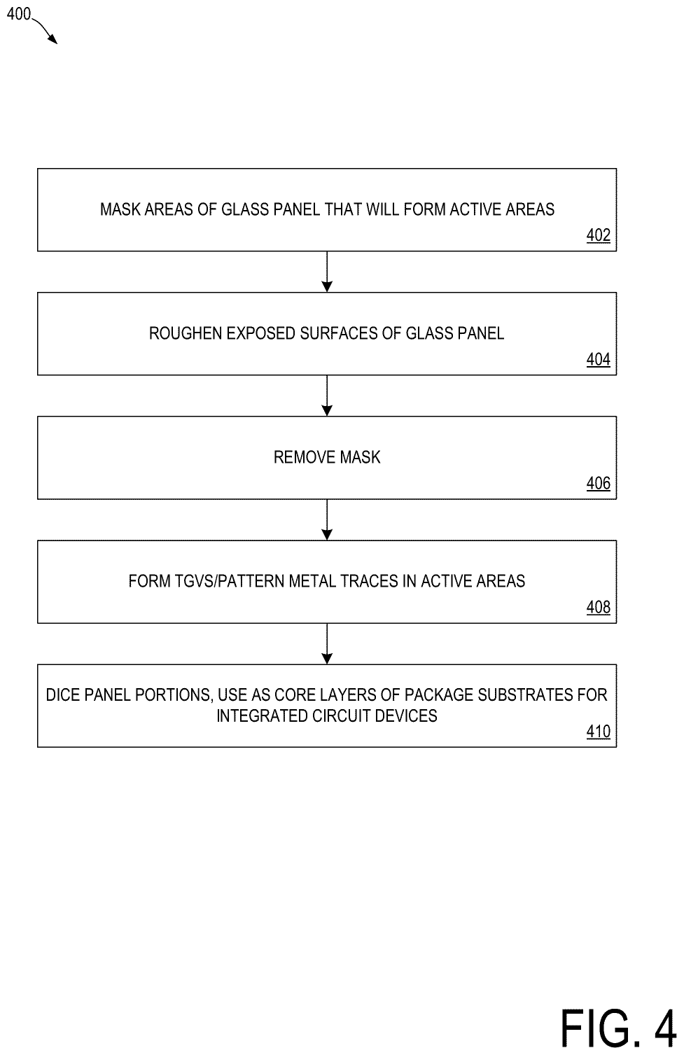

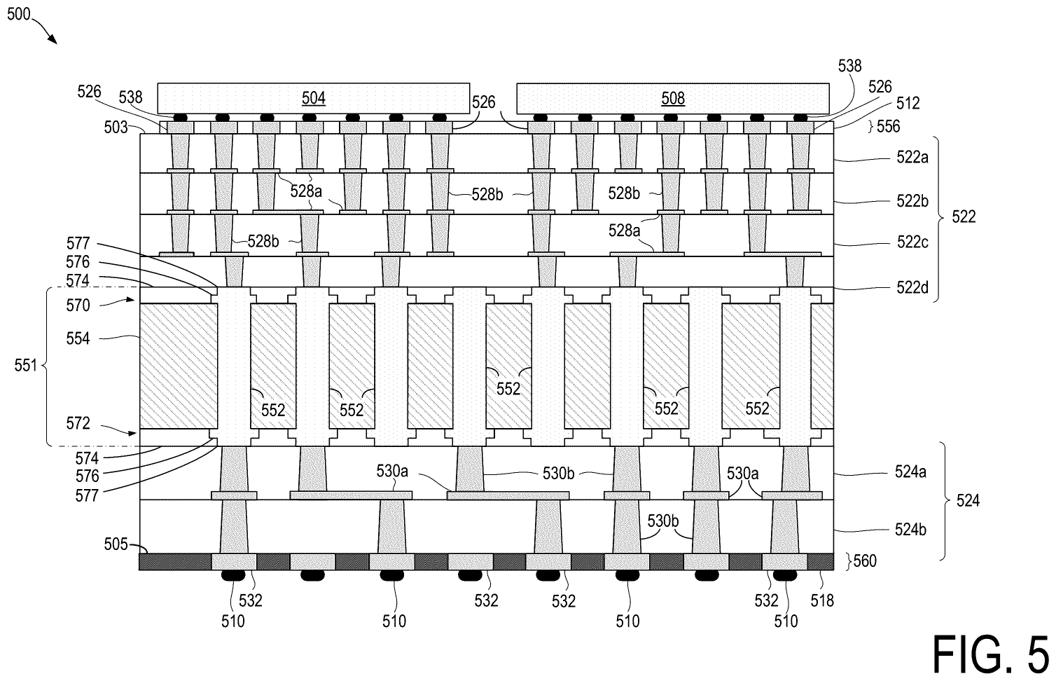

FIG. 4 illustrates an example process 400 of selectively roughening portions of a glass panel in accordance with embodiments herein. The process 400 can be implemented or performed, for example, by an integrated circuit component manufacturer. The example process may include additional, fewer, or different operations than those shown or described below. In some embodiments, one or more of the operations shown include multiple operations, sub-operations, etc. At 402, areas of the glass panel that will form active areas, e.g., areas that include circuitry, traces, TGVs, etc., are masked. Referring to the example shown in FIG. 3 and described above, the areas 304 of the panel 300 would be masked. Next, at 404, the exposed areas (e.g., the areas 306, 308) are roughened, e.g., using a wet or dry etch process as described above. Then, the hard mask material is removed at 406, and metal is deposited/patterned within the active areas of the glass panel. This may include forming TGVs, patterning traces, etc. In some embodiments, additional selective roughening may be performed in certain portions of the active areas (e.g., on surfaces of TGV holes or in areas surrounding TGVs) before the metal is deposited/patterned. After the active areas have been patterned, the panel is diced into different portions (e.g., the portions 302 of the example panel 300 of FIG. 3) so that they may be used as core layers of package substrates for integrated circuit devices, such as the one shown in FIG. 5 and described below.

FIG. 5 is a simplified cross-sectional view of an example portion of a substrate of an integrated circuit component, the substrate comprising a glass core. The substrate portion 500 comprises a glass core 551 positioned between a first set of dielectric layers (which may also be referred to as build-up layers or redistribution layers (RDLs)) 522 (522a, 522b, 522c. 522d) and a second set of dielectric layers 524 (524a, 524b). The glass core 551 may include one or more surfaces that have been roughened in accordance with embodiments herein. For example, a top and/or bottom surface of the glass core 551 may be roughened, e.g., the surfaces interfacing with the encapsulation layers 570 and 572. In some embodiments, this may include the portion of the top/bottom surfaces of the glass core 551 that are in contact with the through-glass vias 552. Additionally, in some embodiments, this may include an outer/border edge of the top/bottom surfaces of the glass core 551, e.g., as described above with respect to FIG. 3. In certain embodiments, the surfaces of the holes within the glass core 551, i.e., those in contact with the through-glass vias 552, may be roughened.

The first set of dielectric layers 522 and the second set of the dielectric layers 524 are stacked vertically. That is, the individual first dielectric layers 522 (e.g., 522a) are positioned adjacent to another first dielectric layer 522 (e.g., 522b) and the individual second dielectric layers 524 (e.g., 524a) are positioned adjacent to another second dielectric layer 524 (e.g., 524b). The glass core 551 comprises a layer of glass 554, encapsulation layers 570 and 572, and through-glass vias 552 located in the layer of glass 554. The encapsulation layers 570 and 572 comprise dielectric layers 574 in which through-glass via pads 576 are located. The through-glass vias 552 comprise protrusions 577. The through-glass vias 552 can be plated through-glass vias and in such embodiments, the metal layer positioned adjacent to an inner wall of the hole in the layer of glass 554 through which a through-glass vias 552 extends, extends into a portion of the pads 576.

An upper surface contact layer 556 comprises a solder resist or other suitable dielectric material 512 and conductive contacts 526 arranged to correspond to the pinouts of dies 504 and 508 directly attached to substrate portion 500. The upper surface contact layer 556 (and hence, the conductive contacts 526) are located on a top dielectric layer (e.g., 522a) of the first dielectric layers 522. A lower surface contact layer 560 comprises a solder resist or other suitable dielectric material 518 and conductive contacts 532 are arranged to correspond to a desired package-level pinout. The lower surface contact layer 560 (and hence, the conductive contacts 532) is located on a bottom dielectric layer (e.g., 524b) of the second dielectric layers 524. Dielectric layers 522 comprise conductive traces (metal lines) 528a and vias 528b, and dielectric layers 524 comprise conductive traces 530a and vias 530b.

Integrated circuit dies 504 and 508 are attached to the substrate portion 500 at conductive contacts 526 via solder balls 538. In other embodiments, the dies 504 and 508 can be attached to the substrate portion 500 via other approaches, such as hybrid bonding. The substrate portion 500 further comprises solder balls 510 attached to conductive contacts 532. In other embodiments, the substrate portion 500 does not comprise solder balls 510 and the substrate portion 500 can attach to other components, such as a printed circuit board, via conductive contacts 532 that are pads.

In various embodiments, an RDL, dielectric, or build-up layer (e.g., layers 522a, 522b, 522c, 524a, 524b) comprises a dielectric material and may include a suitable nitride or oxide, such as silicon dioxide (SiO₂), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen). In some embodiments, an RDL comprises a photo-imagable dielectric (PID). In some embodiments, an RDL comprises an Ajinomoto Build-Up film (often referred to as ABF), which is a material that comprises an organic resin matrix with different types of fillers (for example, silica fillers of different sizes, or hollow fillers of different sizes) to control the coefficient of thermal expansion (CTE) and/or electrical properties of the RDLs (e.g., the dielectric constant (Dk), and/or dissipation factor (insertion loss) (Df)). Although the figures illustrate four RDL layers 524 position above the glass core and two RDL 524 layers below the glass core, in practice, there can be any number of RDL layers in a substrate package. For example, in server applications, an integrated circuit component package can comprise up to 10-20 RDL layers.

As used herein, “interconnect structures” can comprise one or more conductive traces, one or more vias, or a combination thereof. The term conductive trace can refer to via contacts, which can be metal lines to which vias connect and do not comprise a lateral signal routing portion. Interconnect structures can be present in various RDLs, dielectric layers, build-up layers, or glass layers, and can span multiple such layers. Interconnect structures may collectively provide an electrically conductive path from a feature on a first surface 503 of the substrate portion 500 to a feature on a second surface 505 of the substrate portion 500. In various embodiments, an interconnect structure in the first dielectric layer 522 is attached to an interconnect structure in the second dielectric layer 524 by a through-glass via 552, thereby providing an electrically conductive path through the package substrate portion 500. The conductive traces, via contacts, and vias can comprise an electrically conductive material such as a metal (e.g., copper, aluminum, nickel, cobalt, iron, tin, gold, silver, or combinations thereof.

An integrated circuit component comprising a substrate with a glass core comprising any of the through-glass vias described herein can be attached to a printed circuit board. In some embodiments, one or more additional integrated circuit components can be attached to the circuit board. In some embodiments, the printed circuit board and the integrated circuit component can be located in a computing device that comprises a housing that encloses the printed circuit board and the integrated circuit component.

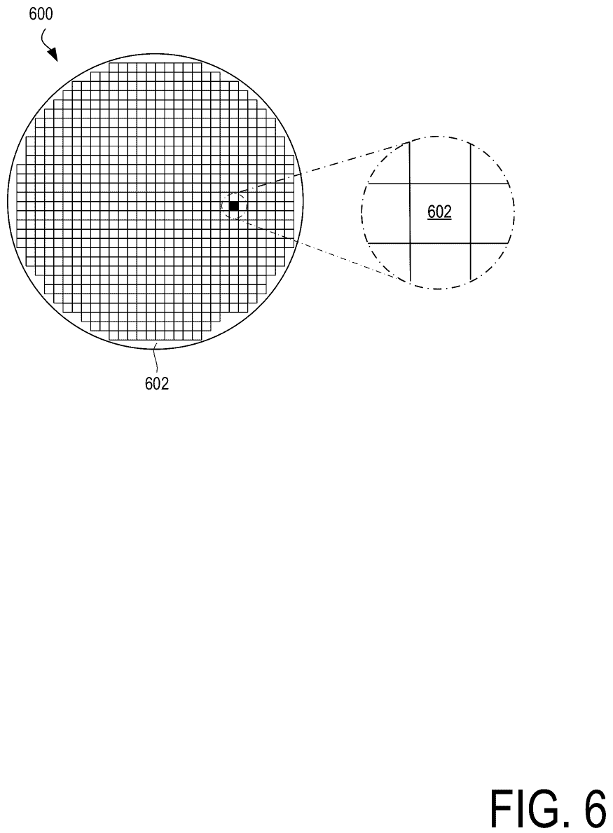

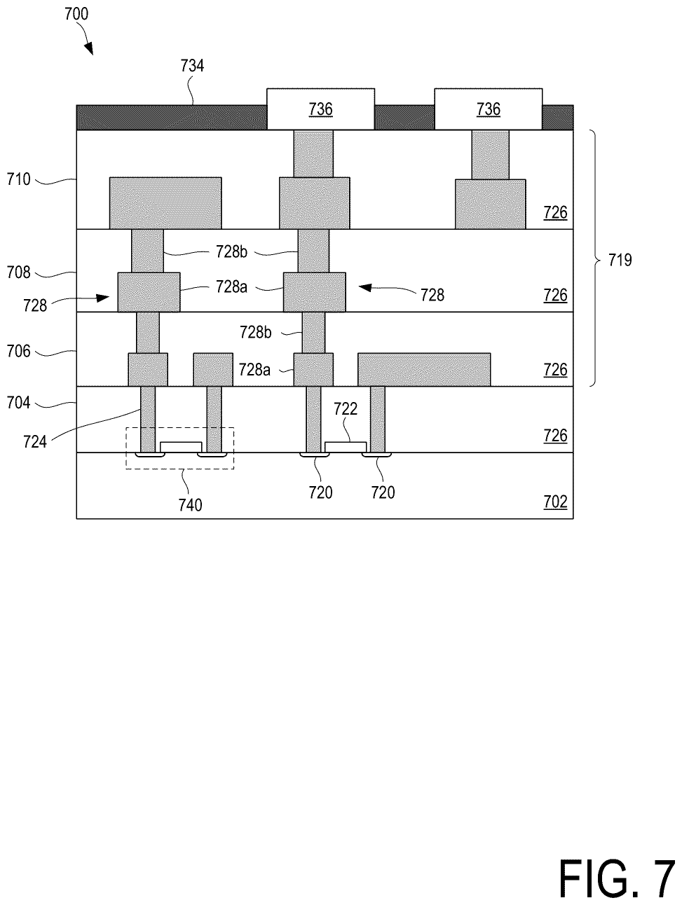

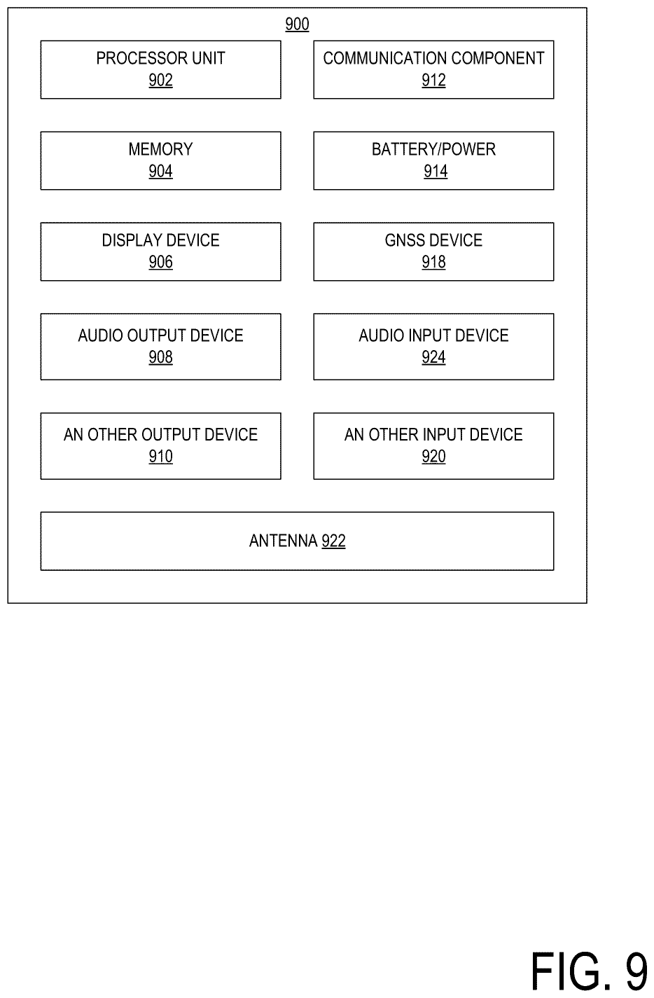

FIG. 6 is a top view of a wafer 600 and dies 602 that may be attached to any of the integrated circuit component package substrates or substrate portions disclosed herein (e.g., as any suitable ones of the dies 504, 508). The wafer 600 may be composed of semiconductor material and may include one or more dies 602 having integrated circuit structures formed on a surface of the wafer 600. The individual dies 602 may be a repeating unit of an integrated circuit product that includes any suitable integrated circuit. After the fabrication of the semiconductor product is complete, the wafer 600 may undergo a singulation process in which the dies 602 are separated from one another to provide discrete “chips” of the integrated circuit product. The die 602 may be any of the dies 500, 508 disclosed herein. The die 602 may include one or more transistors (e.g., some of the transistors 740 of FIG. 7, discussed below), supporting circuitry to route electrical signals to the transistors, passive components (e.g., signal traces, resistors, capacitors, or inductors), and/or any other integrated circuit components. In some embodiments, the wafer 600 or the die 602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 602. For example, a memory array formed by multiple memory devices may be formed on a same die 602 as a processor unit (e.g., the processor unit 902 of FIG. 9) or other logic that is configured to store information in the memory devices or execute instructions stored in the memory array. Various ones of the substrates disclosed herein may be manufactured using a die-to-wafer assembly technique in which some dies are attached to a wafer 600 that include other dies, and the wafer 600 is subsequently singulated.

FIG. 7 is a cross-sectional side view of an integrated circuit device 700 that may be included in any of the integrated circuit components disclosed herein. One or more of the integrated circuit devices 700 may be included in one or more dies 602 (FIG. 6). The integrated circuit device 700 may be formed on a die substrate 702 (e.g., the wafer 600 of FIG. 6) and may be included in a die (e.g., the die 602 of FIG. 6). The die substrate 702 may be a semiconductor substrate composed of semiconductor material systems including, for example, n-type or p-type materials systems (or a combination of both). The die substrate 702 may include, for example, a crystalline substrate formed using a bulk silicon or a silicon-on-insulator (SOI) substructure. In some embodiments, the die substrate 702 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 702. Although a few examples of materials from which the die substrate 702 may be formed are described here, any material that may serve as a foundation for an integrated circuit device 700 may be used. The die substrate 702 may be part of a singulated die (e.g., the dies 602 of FIG. 6) or a wafer (e.g., the wafer 600 of FIG. 6).

The integrated circuit device 700 may include one or more device layers 704 disposed on the die substrate 702. The device layer 704 may include features of one or more transistors 740 (e.g., metal oxide semiconductor field-effect transistors (MOSFETs)) formed on the die substrate 702. The transistors 740 may include, for example, one or more source and/or drain (S/D) regions 720, a gate 722 to control current flow between the S/D regions 720, and one or more S/D contacts 724 to route electrical signals to/from the S/D regions 720. The transistors 740 may include additional features not depicted for the sake of clarity, such as device isolation regions, gate contacts, and the like. The transistors 740 are not limited to the type and configuration depicted in FIG. 7 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

A transistor 740 may include a gate 722 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 740 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill material layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 740 along the source-channel-drain direction, the gate electrode may consist of a U-shaped structure that includes a bottom portion substantially parallel to the surface of the die substrate 702 and two sidewall portions that are substantially perpendicular to the top surface of the die substrate 702. In other embodiments, at least one of the metal layers that form the gate electrode may simply be a planar layer that is substantially parallel to the top surface of the die substrate 702 and does not include sidewall portions substantially perpendicular to the top surface of the die substrate 702. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 720 may be formed within the die substrate 702 adjacent to the gate 722 of individual transistors 740. The S/D regions 720 may be formed using an implantation/diffusion process or an etching/deposition process, for example. In the former process, dopants such as boron, aluminum, antimony, phosphorous, or arsenic may be ion-implanted into the die substrate 702 to form the S/D regions 720. An annealing process that activates the dopants and causes them to diffuse farther into the die substrate 702 may follow the ion-implantation process. In the latter process, the die substrate 702 may first be etched to form recesses at the locations of the S/D regions 720. An epitaxial deposition process may then be carried out to fill the recesses with material that is used to fabricate the S/D regions 720. In some implementations, the S/D regions 720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 720 may be formed using one or more alternate semiconductor materials such as germanium or a group III-V material or alloy. In further embodiments, one or more layers of metal and/or metal alloys may be used to form the S/D regions 720.

Electrical signals, such as power and/or input/output (I/O) signals, may be routed to and/or from the devices (e.g., transistors 740) of the device layer 704 through one or more interconnect layers disposed on the device layer 704 (illustrated in FIG. 7 as interconnect layers 706-710). For example, electrically conductive features of the device layer 704 (e.g., the gate 722 and the S/D contacts 724) may be electrically coupled with the interconnect structures 728 of the interconnect layers 706-710. The one or more interconnect layers 706-710 may form a metallization stack (also referred to as an “ILD stack”) 719 of the integrated circuit device 700.

The interconnect structures 728 may be arranged within the interconnect layers 706-710 to route electrical signals according to a wide variety of designs; in particular, the arrangement is not limited to the particular configuration of interconnect structures 728 depicted in FIG. 7. Although a particular number of interconnect layers 706-710 is depicted in FIG. 7, embodiments of the present disclosure include integrated circuit devices having more or fewer interconnect layers than depicted.

In some embodiments, the interconnect structures 728 may include lines 728a and/or vias 728b filled with an electrically conductive material such as a metal. The lines 728a may be arranged to route electrical signals in a direction of a plane that is substantially parallel with a surface of the die substrate 702 upon which the device layer 704 is formed. For example, the lines 728a may route electrical signals in a direction in and out of the page and/or in a direction across the page from the perspective of FIG. 7. The vias 728b may be arranged to route electrical signals in a direction of a plane that is substantially perpendicular to the surface of the die substrate 702 upon which the device layer 704 is formed. In some embodiments, the vias 728b may electrically couple lines 728a of different interconnect layers 706-710 together.

The interconnect layers 706-710 may include a dielectric material 726 disposed between the interconnect structures 728, as shown in FIG. 7. In some embodiments, dielectric material 726 disposed between the interconnect structures 728 in different ones of the interconnect layers 706-710 may have different compositions; in other embodiments, the composition of the dielectric material 726 between different interconnect layers 706-710 may be the same. The device layer 704 may include a dielectric material 726 disposed between the transistors 740 and a bottom layer of the metallization stack as well. The dielectric material 726 included in the device layer 704 may have a different composition than the dielectric material 726 included in the interconnect layers 706-710; in other embodiments, the composition of the dielectric material 726 in the device layer 704 may be the same as a dielectric material 726 included in any one of the interconnect layers 706-710.

A first interconnect layer 706 (referred to as Metal 1 or “M1”) may be formed directly on the device layer 704. In some embodiments, the first interconnect layer 706 may include lines 728a and/or vias 728b, as shown. The lines 728a of the first interconnect layer 706 may be coupled with contacts (e.g., the S/D contacts 724) of the device layer 704. The vias 728b of the first interconnect layer 706 may be coupled with the lines 728a of a second interconnect layer 708.

The second interconnect layer 708 (referred to as Metal 2 or “M2”) may be formed directly on the first interconnect layer 706. In some embodiments, the second interconnect layer 708 may include via 728b to couple the lines 728 of the second interconnect layer 708 with the lines 728a of a third interconnect layer 710. Although the lines 728a and the vias 728b are structurally delineated with a line within individual interconnect layers for the sake of clarity, the lines 728a and the vias 728b may be structurally and/or materially contiguous (e.g., simultaneously filled during a dual-damascene process) in some embodiments.

The third interconnect layer 710 (referred to as Metal 3 or “M3”) (and additional interconnect layers, as desired) may be formed in succession on the second interconnect layer 708 according to similar techniques and configurations described in connection with the second interconnect layer 708 or the first interconnect layer 706. In some embodiments, the interconnect layers that are “higher up” in the metallization stack 719 in the integrated circuit device 700 (i.e., farther away from the device layer 704) may be thicker that the interconnect layers that are lower in the metallization stack 719, with lines 728a and vias 728b in the higher interconnect layers being thicker than those in the lower interconnect layers.

The integrated circuit device 700 may include a solder resist material 734 (e.g., polyimide or similar material) and one or more conductive contacts 736 formed on the interconnect layers 706-710. In FIG. 7, the conductive contacts 736 are illustrated as taking the form of bond pads. The conductive contacts 736 may be electrically coupled with the interconnect structures 728 and configured to route the electrical signals of the transistor(s) 740 to external devices. For example, solder bonds may be formed on the one or more conductive contacts 736 to mechanically and/or electrically couple an integrated circuit die including the integrated circuit device 700 with another component (e.g., a printed circuit board). The integrated circuit device 700 may include additional or alternate structures to route the electrical signals from the interconnect layers 706-710; for example, the conductive contacts 736 may include other analogous features (e.g., posts) that route the electrical signals to external components. The conductive contacts 736 may serve as the conductive contacts 426, as appropriate.

In some embodiments in which the integrated circuit device 700 is a double-sided die, the integrated circuit device 700 may include another metallization stack (not shown) on the opposite side of the device layer(s) 704. This metallization stack may include multiple interconnect layers as discussed above with reference to the interconnect layers 706-710, to provide conductive pathways (e.g., including conductive lines and vias) between the device layer(s) 704 and additional conductive contacts (not shown) on the opposite side of the integrated circuit device 700 from the conductive contacts 736. These additional conductive contacts may serve as the conductive contacts 432, as appropriate.

In other embodiments in which the integrated circuit device 700 is a double-sided die, the integrated circuit device 700 may include one or more through silicon vias (TSVs) through the die substrate 702; these TSVs may make contact with the device layer(s) 704, and may provide conductive pathways between the device layer(s) 704 and additional conductive contacts (not shown) on the opposite side of the integrated circuit device 700 from the conductive contacts 736. In some embodiments, TSVs extending through the substrate can be used for routing power and ground signals from conductive contacts on the opposite side of the integrated circuit device 700 from the conductive contacts 736 to the transistors 740 and any other components integrated into the die 700, and the metallization stack 719 can be used to route I/O signals from the conductive contacts 736 to transistors 740 and any other components integrated into the die 700.

Multiple integrated circuit devices 700 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

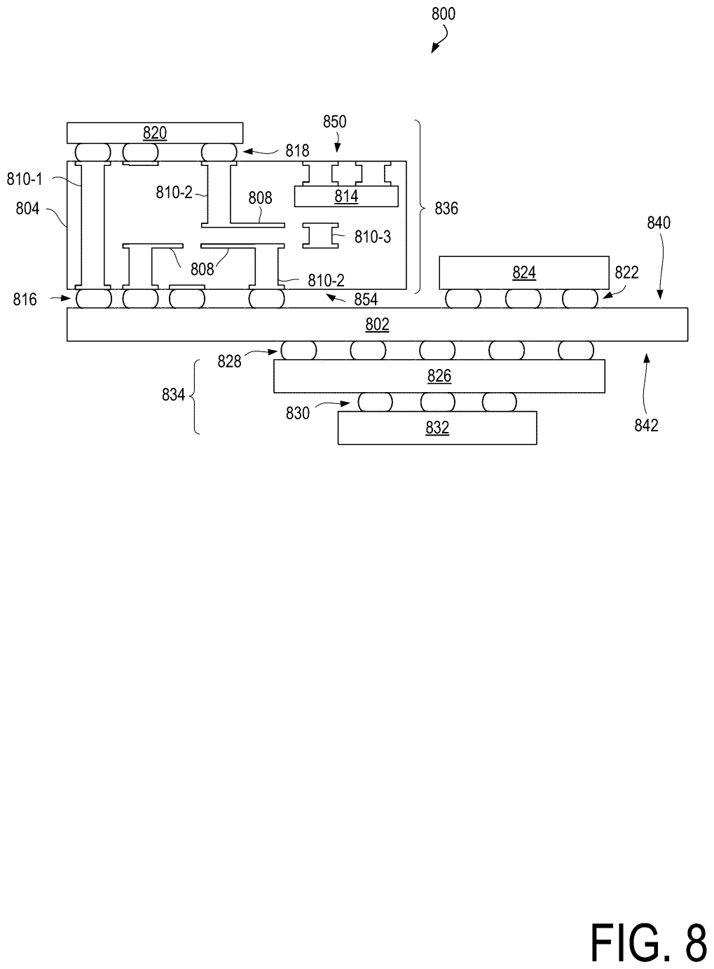

FIG. 8 is a cross-sectional side view of an integrated circuit device assembly 800 that may include any of the glass cores disclosed herein. In some embodiments, the integrated circuit device assembly 800 may be integrated circuit component package substrate that include substrate portion 400. The integrated circuit device assembly 800 includes a number of components disposed on a circuit board 802 (which may be a motherboard, system board, mainboard, etc.). The integrated circuit device assembly 800 includes components disposed on a first face 840 of the circuit board 802 and an opposing second face 842 of the circuit board 802; generally, components may be disposed on one or both faces 840 and 842. Any of the integrated circuit components discussed below with reference to the integrated circuit device assembly 800 may take the form of or comprise any suitable ones of the embodiments of an integrated circuit component package substrates or substrate portions described herein.

In some embodiments, the circuit board 802 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 802. In other embodiments, the circuit board 802 may be a non-PCB substrate. In some embodiments the circuit board 802 may be, for example, a printed circuit board attached to the bottom of any of the substrate or substrate portions disclosed herein. The integrated circuit device assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802, and may include solder balls (as shown in FIG. 8), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 816 may serve as the coupling components illustrated or described for any of the substrate or substrate portion described herein, as appropriate.

The package-on-interposer structure 836 may include an integrated circuit component 820 coupled to an interposer 804 by coupling components 818. The coupling components 818 may take any suitable form for the application, such as the forms discussed above with reference to the coupling components 816. Although a single integrated circuit component 820 is shown in FIG. 8, multiple integrated circuit components may be coupled to the interposer 804; indeed, additional interposers may be coupled to the interposer 804. The interposer 804 may provide an intervening substrate used to bridge the circuit board 802 and the integrated circuit component 820.

The integrated circuit component 820 may be a packaged or unpacked integrated circuit product that includes one or more integrated circuit dies (e.g., the die 602 of FIG. 6, the integrated circuit device 700 of FIG. 7) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 820, a single monolithic integrated circuit die comprises solder bumps attached to contacts on the die. The solder bumps allow the die to be directly attached to the interposer 804. The integrated circuit component 820 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 820 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 820 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 820 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 804 may spread connections to a wider pitch or reroute a connection to a different connection. For example, the interposer 804 may couple the integrated circuit component 820 to a set of ball grid array (BGA) conductive contacts of the coupling components 816 for coupling to the circuit board 802. In the embodiment illustrated in FIG. 8, the integrated circuit component 820 and the circuit board 802 are attached to opposing sides of the interposer 804; in other embodiments, the integrated circuit component 820 and the circuit board 802 may be attached to a same side of the interposer 804. In some embodiments, three or more components may be interconnected by way of the interposer 804.

In some embodiments, the interposer 804 may be formed as a PCB, including multiple metal layers separated from one another by layers of dielectric material and interconnected by electrically conductive vias. In some embodiments, the interposer 804 may be formed of an epoxy resin, a fiberglass-reinforced epoxy resin, an epoxy resin with inorganic fillers, a ceramic material, or a polymer material such as polyimide. In some embodiments, the interposer 804 may be formed of alternate rigid or flexible materials that may include the same materials described above for use in a semiconductor substrate, such as silicon, germanium, and other group III-V and group IV materials. The interposer 804 may include metal interconnects 808 and vias 810, including but not limited to through hole vias 810-1 (that extend from a first face 850 of the interposer 804 to a second face 854 of the interposer 804), blind vias 810-2 (that extend from the first or second faces 850 or 854 of the interposer 804 to an internal metal layer), and buried vias 810-3 (that connect internal metal layers).

In some embodiments, the interposer 804 can comprise a silicon interposer. Through silicon vias (TSV) extending through the silicon interposer can connect connections on a first face of a silicon interposer to an opposing second face of the silicon interposer. In some embodiments, an interposer 804 comprising a silicon interposer can further comprise one or more routing layers to route connections on a first face of the interposer 804 to an opposing second face of the interposer 804.

The interposer 804 may further include embedded devices 814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art. In embodiments where the interposer is a non-printed circuit board

The integrated circuit device assembly 800 may include an integrated circuit component 824 coupled to the first face 840 of the circuit board 802 by coupling components 822. The coupling components 822 may take the form of any of the embodiments discussed above with reference to the coupling components 816, and the integrated circuit component 824 may take the form of any of the embodiments discussed above with reference to the integrated circuit component 820.

The integrated circuit device assembly 800 illustrated in FIG. 8 includes a package-on-package structure 834 coupled to the second face 842 of the circuit board 802 by coupling components 828. The package-on-package structure 834 may include an integrated circuit component 826 and an integrated circuit component 832 coupled together by coupling components 830 such that the integrated circuit component 826 is disposed between the circuit board 802 and the integrated circuit component 832. The coupling components 828 and 830 may take the form of any of the embodiments of the coupling components 816 discussed above, and the integrated circuit components 826 and 832 may take the form of any of the embodiments of the integrated circuit component 820 discussed above. The package-on-package structure 834 may be configured in accordance with any of the package-on-package structures known in the art.

FIG. 9 is a block diagram of an example electrical device 900 that may include one or more substrate packages comprise a glass core with the through-glass vias disclosed herein. For example, any suitable ones of the components of the electrical device 900 may include one or more of the integrated circuit device assemblies 800, integrated circuit components 820, integrated circuit devices 700, or integrated circuit dies 602 disclosed herein, and may be arranged in any of the microelectronic assemblies, integrated circuit component packages, or integrated circuit component substrates disclosed herein. A number of components are illustrated in FIG. 9 as included in the electrical device 900, but any one or more of these components may be omitted or duplicated, as suitable for the application. In some embodiments, some or all of the components included in the electrical device 900 may be attached to one or more motherboards mainboards, or system boards. In some embodiments, one or more of these components are fabricated onto a single system-on-a-chip (SoC) die.

Additionally, in various embodiments, the electrical device 900 may not include one or more of the components illustrated in FIG. 9, but the electrical device 900 may include interface circuitry for coupling to the one or more components. For example, the electrical device 900 may not include a display device 906, but may include display device interface circuitry (e.g., a connector and driver circuitry) to which a display device 906 may be coupled. In another set of examples, the electrical device 900 may not include an audio input device 924 or an audio output device 908, but may include audio input or output device interface circuitry (e.g., connectors and supporting circuitry) to which an audio input device 924 or audio output device 908 may be coupled.

The electrical device 900 may include one or more processor units 902 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 902 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 900 may include a memory 904, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 904 may include memory that is located on the same integrated circuit die as the processor unit 902. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 900 can comprise one or more processor units 902 that are heterogeneous or asymmetric to another processor unit 902 in the electrical device 900. There can be a variety of differences between the processing units 902 in a system in terms of a spectrum of metrics of merit including architectural, microarchitectural, thermal, power consumption characteristics, and the like. These differences can effectively manifest themselves as asymmetry and heterogeneity among the processor units 902 in the electrical device 900.

In some embodiments, the electrical device 900 may include a communication component 912 (e.g., one or more communication components). For example, the communication component 912 can manage wireless communications for the transfer of data to and from the electrical device 900. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 912 may operate in accordance with other wireless protocols in other embodiments. The electrical device 900 may include an antenna 922 to facilitate wireless communications and/or to receive other wireless communications (such as AM or FM radio transmissions).

In some embodiments, the communication component 912 may manage wired communications, such as electrical, optical, or any other suitable communication protocols (e.g., IEEE 802.3 Ethernet standards). As noted above, the communication component 912 may include multiple communication components. For instance, a first communication component 912 may be dedicated to shorter-range wireless communications such as Wi-Fi or Bluetooth, and a second communication component 912 may be dedicated to longer-range wireless communications such as global positioning system (GPS), EDGE, GPRS, CDMA, WiMAX, LTE, EV-DO, or others. In some embodiments, a first communication component 912 may be dedicated to wireless communications, and a second communication component 912 may be dedicated to wired communications.

The electrical device 900 may include battery/power circuitry 914. The battery/power circuitry 914 may include one or more energy storage devices (e.g., batteries or capacitors) and/or circuitry for coupling components of the electrical device 900 to an energy source separate from the electrical device 900 (e.g., AC line power).

The electrical device 900 may include a display device 906 (or corresponding interface circuitry, as discussed above). The display device 906 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 900 may include an audio output device 908 (or corresponding interface circuitry, as discussed above). The audio output device 908 may include any embedded or wired or wirelessly connected external device that generates an audible indicator, such speakers, headsets, or earbuds.

The electrical device 900 may include an audio input device 924 (or corresponding interface circuitry, as discussed above). The audio input device 924 may include any embedded or wired or wirelessly connected device that generates a signal representative of a sound, such as microphones, microphone arrays, or digital instruments (e.g., instruments having a musical instrument digital interface (MIDI) output). The electrical device 900 may include a Global Navigation Satellite System (GNSS) device 918 (or corresponding interface circuitry, as discussed above), such as a Global Positioning System (GPS) device. The GNSS device 918 may be in communication with a satellite-based system and may determine a geolocation of the electrical device 900 based on information received from one or more GNSS satellites, as known in the art.

The electrical device 900 may include an other output device 910 (or corresponding interface circuitry, as discussed above). Examples of the other output device 910 may include an audio codec, a video codec, a printer, a wired or wireless transmitter for providing information to other devices, or an additional storage device.

The electrical device 900 may include an other input device 920 (or corresponding interface circuitry, as discussed above). Examples of the other input device 920 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 900 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 900 may be any other electronic device that processes data. In some embodiments, the electrical device 900 may comprise multiple discrete physical components. Given the range of devices that the electrical device 900 can be manifested as in various embodiments, in some embodiments, the electrical device 900 can be referred to as a computing device or a computing system.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C). Further, it should be appreciated that items included in a list in the form of “at least one of A, B, and C” can mean (A); (B); (C); (A and B); (A and C); (B and C); or (A, B, and C). Similarly, items listed in the form of “at least one of A, B, or C” can mean (A); (B); (C); (A and B); (A and C); (B and C); or (A, B, and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature. Further, as used herein, the phrase “located on” in the context of a first layer or component located on a second layer or component may refer to the first layer or component being directly physically attached to the second part or component (no layers or components between the first and second layers or components) or physically attached to the second layer or component with one or more intervening layers or components. Additionally, as used herein, the term “adjacent” may refer to layers or components that are in physical contact with each other. That is, there is no layer or component between the stated adjacent layers or components. For example, a layer X that is adjacent to a layer Y refers to a layer that is in physical contact with layer Y.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated. Additionally, the terms “substantially,” “close,” “approximately,” “near,” and “about,” generally refer to being within +/−10% of a target value (unless specifically specified).

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.
Example 1 is an integrated circuit package substrate comprising: a core layer comprising Silicon and Oxygen, at least one surface of the core layer having a roughened surface; and a plurality of metal vias in holes of the core layer, the metal vias electrically connecting a top side of the core layer and a bottom side of the core layer; and a plurality of build-up layers on the core layer, the build-up layers comprising interconnect structures electrically connected to the metal vias in the core layer.
Example 2 includes the subject matter of Example 1, wherein the roughened surface
has an average roughness above 100 nm.
Example 2.1 includes the subject matter of Example 1, wherein the roughened surface has an average roughness above 50 nm.
Example 2.2 includes the subject matter of Example 1, wherein the roughened surface has an average roughness above 30 nm.
Example 2.3 includes the subject matter of Example 1, wherein the roughened surface has an average roughness above 20 nm.
Example 2.4 includes the subject matter of any preceding Example, wherein the core layer comprises at least one smooth surface with an average roughness that is substantially less than the roughness of the roughened surface.
Example 3 includes the subject matter of any preceding Example, wherein the roughened surface has an average roughness of approximately 200 nm.
Example 4 includes the subject matter of any one of Examples 1-3, wherein a first portion of the top surface of the core layer has a roughened surface, and a second portion of the top surface is smooth.
Example 5 includes the subject matter of Example 4, wherein surfaces of the core layer in contact with the metal vias are smooth.
Example 6 includes the subject matter of Example 4, wherein surfaces of the core layer in contact with the metal vias are roughened.
Example 7 includes the subject matter of Example 6, wherein surfaces of the core layer not in contact with the metal vias are smooth.
Example 8 includes the subject matter of any one of Examples 1-7, wherein surfaces of the holes in the core layer are roughened.
Example 9 includes the subject matter of any one of Examples 1-8, wherein an outer edge of the top surface of the core layer is roughened.
Example 10 includes the subject matter of any one of Examples 1-9, wherein the core layer comprises silica.
Example 11 includes the subject matter of any one of Examples 1-10, wherein the core layer comprises a doped silicate.
Example 12 is a system comprising: a package substrate comprising: a glass layer having at least one roughened surface (e.g., with an average roughness above 100 nm); and a metal in contact with the roughened surface of the glass layer; and an integrated circuit die coupled to the package substrate.
Example 12.1 includes the subject matter of Example 12, wherein the glass layer has at least one smooth surface with an average roughness (e.g., less than 100 nm) that is substantially less than the average roughness of the roughened surface.
Example 13 includes the subject matter of Example 12, wherein the roughened surface has an average roughness of approximately 200 nm.
Example 14 includes the subject matter of Example 12 or 13, wherein an outer edge of a top surface or bottom surface of the glass layer has a roughened surface.
Example 15 includes the subject matter of any one of Examples 12-14, wherein the package substrate comprises a metal via in the glass layer and the metal via is in contact with a roughened surface of the glass layer.
Example 16 includes the subject matter of Example 15, wherein the roughened surface of the glass layer in contact with the metal via is a top surface of the glass layer.
Example 17 includes the subject matter of Example 15 or 16, wherein the roughened surface of the glass layer in contact with the metal via is a surface inside a hole of the glass layer in which the metal via is disposed.
Example 18 includes the subject matter of any one of Examples 12-17, wherein the package substrate comprises a metal via in the glass layer and the metal via is in contact with a smooth surface of the glass layer.
Example 19 is a method comprising: depositing a hard mask material on a glass layer; etching exposed surfaces of the glass layer; removing the hard mask material; and depositing a metal on the glass layer.
Example 20 includes the subject matter of Example 19, wherein etching the exposed surfaces of the glass layer comprises etching an outer edge of the glass layer.
Example 21 includes the subject matter of Example 19 or 20, wherein etching the exposed surfaces of the glass layer comprises performing a wet etch process using at least one of NaOH or HF.
Example 22 includes the subject matter of Example 19 or 20, wherein etching the exposed surfaces of the glass layer comprises performing a dry etch process using plasma.
Example 23 includes the subject matter of any one of Examples 19-22, wherein depositing a metal on the glass layer comprises depositing the metal on a surface of the glass layer that was etched.
Example 24 includes the subject matter of any one of Examples 19-23, wherein depositing a metal on the glass layer comprises forming a through-glass via in the glass layer.
Example 25 includes the subject matter of any one of Examples 19-24, further comprising dividing the glass layer into a plurality of portions after etching.

1. An integrated circuit package substrate comprising:
a core layer comprising Silicon and Oxygen, at least one surface of the core layer having a roughened surface; and
a plurality of metal vias in holes of the core layer, the metal vias electrically connecting a top side of the core layer and a bottom side of the core layer; and
a plurality of build-up layers on the core layer, the build-up layers comprising interconnect structures electrically connected to the metal vias in the core layer.

2. The integrated circuit package substrate of claim 1, wherein the roughened surface has an average roughness above 100 nm.

3. The integrated circuit package substrate of claim 1, wherein a first portion of the top surface of the core layer has a roughened surface, and a second portion of the top surface is smooth.

4. The integrated circuit package substrate of claim 3, wherein surfaces of the core layer in contact with the metal vias are smooth.

5. The integrated circuit package substrate of claim 3, wherein surfaces of the core layer in contact with the metal vias are roughened.

6. The integrated circuit package substrate of claim 5, wherein surfaces of the core layer not in contact with the metal vias are smooth.

7. The integrated circuit package substrate of claim 1, wherein surfaces of the holes in the core layer are roughened.

8. The integrated circuit package substrate of claim 1, wherein an outer edge of the top surface of the core layer is roughened.

9. A system comprising:
a package substrate comprising:
a glass layer having at least one roughened surface with an average roughness above 100 nm; and
a metal in contact with the roughened surface of the glass layer; and
an integrated circuit die coupled to the package substrate.

10. The system of claim 9, wherein an outer edge of a top surface or bottom surface of the glass layer has a roughened surface.

11. The system of claim 9, wherein the package substrate comprises a metal via in the glass layer and the metal via is in contact with a roughened surface of the glass layer.

12. The system of claim 11, wherein the roughened surface of the glass layer in contact with the metal via is a top surface of the glass layer.

13. The system of claim 11, wherein the roughened surface of the glass layer in contact with the metal via is a surface inside a hole of the glass layer in which the metal via is disposed.

14. The system of claim 9, wherein the package substrate comprises a metal via in the glass layer and the metal via is in contact with a smooth surface of the glass layer.

15. A method comprising:
depositing a hard mask material on a glass layer;
etching exposed surfaces of the glass layer;
removing the hard mask material; and
depositing a metal on the glass layer.

16. The method of claim 15, wherein etching the exposed surfaces of the glass layer comprises performing a wet etch process using at least one of NaOH or HF.

17. The method of claim 15, wherein etching the exposed surfaces of the glass layer comprises performing a dry etch process using plasma.

18. The method of 15, wherein depositing a metal on the glass layer comprises depositing the metal on a surface of the glass layer that was etched.

19. The method of 15, wherein depositing a metal on the glass layer comprises forming a through-glass via in the glass layer.

20. The method of 15, further comprising dividing the glass layer into a plurality of portions after etching.
